(19) United States
(12) Patent Application Publication
(10) Pub. No.: US 2012/0243095 A1
(43) Pub. Date: Sep. 27, 2012

(54) CONFIGURABLE MICROMECHANICAL DIFFRACTIVE ELEMENT WITH ANTI STICTION BUMPS

(76) Inventors: Hakon Sagberg, Oslo (NO); Ib-Rune Johansen, Oslo (NO); Sigurd Teodor Moe, Oslo (NO); Matthieu Lacolle, Nesoya (NO); Thor Bakke, Lysaker (NO); Dag Thorstein Wang, Oslo (NO); Elisabeth Larsen Rogne, Oslo (NO); Henrik Rogne, Oslo (NO)

(21) Appl. No.: 13/387,473

(22) PCT Filed: Aug. 13, 2010
(86) PCT No.: PCT/EP10/61850

§ 371 Date: May 2, 2012

(30) Foreign Application Priority Data
Aug. 14, 2009 (NO) 20092837

(51) Int. Cl. G02B 26/00; H01L 21/311

(52) U.S. Cl. 359/568; 438/700; 257/E21.249

(57) ABSTRACT

The invention relates to a micromechanical unit, in particular, an adjustable optical filter, and also a method to manufacture the unit. The unit comprises a first device layer and a second substrate layer at least partially fastened to each other, where the device layer comprises a number of reflecting elements divided between a number of non movable, fixed reflecting elements, where the fixed elements are connected with the substrate, and where a cavity is defined between the substrate and each movable element and each movable element is set up to produce a spring-loaded movement into the cavity, and where a number of dielectric spacer blocks are placed in the cavities between each movable element and the substrate to avoid electric contact between them.

The invention relates to a micromechanical element, in particular, an adjustable optical spectral filter and a method to produce this which, according to prior art, can be realised with the help of a row of alternately movable and fixed optical micro/reflectors, particularly where the reflectors have a diffractive or light deflecting effect.

### BACKGROUND TO THE INVENTION

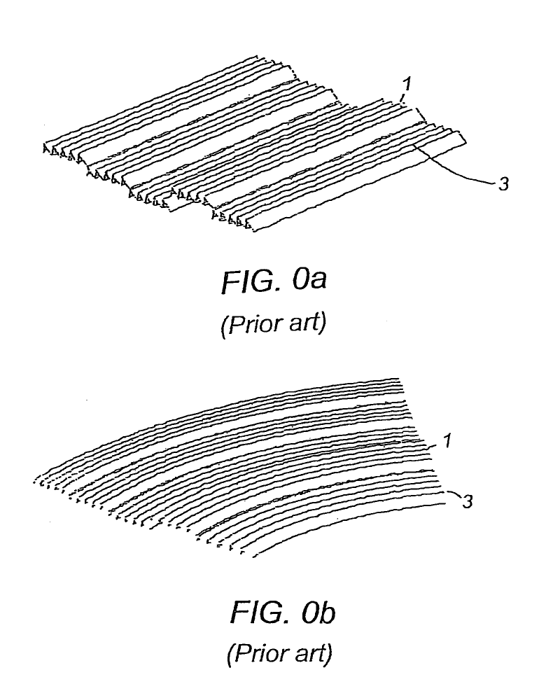

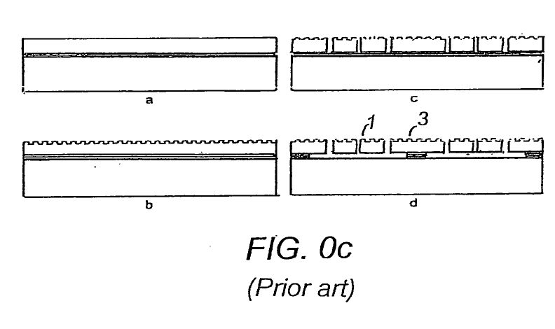

Movable optical micro reflectors used for spectral filtering have been described previously in, among others, the international patent application no. WO 2004/059365, which relates to diffractive optical elements that can be configured, that comprise a series of movable diffractive micro reflectors that go by the name diffractive sub-elements. The reflectors or the sub-elements (1,3, See FIGS. 0a and 0b) have lateral dimensions considerably larger than the displacement, and can have the shape of rectangles (FIG. 0a) or sectors of concentric rings (FIG. 0b). Light reflected from the different sub-elements will interfere, so that one can filter out light of a certain spectral composition, and by adjusting the position of the elements vertically or laterally, one can continuously change the characteristics of the filter.

A special case of the mentioned configurable diffractive elements can be made up of a row where every other reflector can be moved in synchrony and take up two different positions, while the other reflectors are stationary. This results in an optical filter that can alternate between two states: A simple band pass filter and a double band pass filter where the bands lie on their own side of the simple filter. A such alternating filter is very well suited to applications within spectroscopy and infrared gas measurements in particular. A practical embodiment of the filter as a micro-opto-electromechanical system (MOEMS) must meet certain requirements. The positions of the movable reflectors must be adjustable over a distance of a quarter of a wavelength in a direction perpendicular to the optical surfaces. The wavelength is in the infrared area so that the displacement is of the order of 1 micrometre. The reflectors must lie in the same plane. The displacement shall be in synchrony and be able to be repeated, particularly with a frequency in the kilohertz area, and with billions to trillions of cycles within the lifetime of the components. Between the movable reflectors there shall be fixed reflectors which in form and size are approximately similar to the movable reflectors. The reflectors are given diffractive properties in that they are engraved with a relief pattern where the depth of this pattern is of the same order of magnitude as the wavelength. A total area of several square millimetres ought to be covered by reflectors moving in synchrony.

The optical principle for the alternating filter described above is regarded as prior art and a concrete micromechanical shape has been published previously in an article by Håkon Sagberg et al “Two-state Optical Filter Based on Micromechanical Diffractive Elements” presented at IEEE/LEOS International Conference On Optical MEMS and Their Applications in August 2007 (OMEMS2007). FIG. 0c shows an embodiment according to prior art, based on a commercially available silicon wafer, comprising a substrate and a structural layer which are fused together with a thin layer of silicon dioxide. After the diffractive optical surfaces are formed at the top of the structural layer, this is divided up into two sets of beams (1,3) with the help of an etching method. Thereafter, every other beam (3) is made movable by etching away the layer of oxide in selected areas. This is a simple process, but has three essential disadvantages. Firstly, holes must be made in the movable beams so that the gas or the liquid which is used for the etching of the layer of oxide shall be able to enter into it. Secondly, surfaces with different electrical potential will come into contact when the beams are pulled into the substrate, and the electrical current that passes between the surfaces can lead to a large drop in voltage, or result in the beams being fused together with the substrate with the help of the electrical current between them. Thirdly, the contact area between the beams and the substrate becomes large and unpredictable, something which can lead to stiction. Stiction occurs when the adhesive forces between two surfaces become so large that the available forces that are set up do not manage to pull the surfaces apart, and a lasting, unwanted adhesion arises. In this case, the forces that are set up come from elastic bridges in silicon.

To reduce the adhesive forces and avoid stiction, there are several known methods used on different types of electromechanical systems. Particularly important is the use of spacer blocks, also referred to as “landing pads”, “stops”, “bumps” or “dimples”. These shall, as a rule, satisfy two functions: To define an accurate distance as an end stop for one movement, and to prevent stiction by making sure that large areas do not come into contact. See, for example, US 2001/0055831, U.S. Pat. No. 6,437,965, U.S. Pat. No. 6,528,887. Other important techniques for stiction prevention are:
to avoid that surfaces with different electric potential come into contact,
to avoid that a parasitic charging of dielectric materials take place,
to treat the surfaces chemically or mechanically to introduce roughness and reduce the contact area, and
to treat the surfaces chemically to increase their water repellent characteristics,
to wrap the electromechanical system hermetically to avoid moisture, so that the water repelling characteristics of the surfaces become less important.

The existing solutions are, to a large extent, adapted to the specific needs of the individual micromechanical systems, and there are no standard methods. Some typical problems with the existing solutions are that:

The manufacturing method can be very complicated when one must use spacer blocks, the form of the spacer blocks can come to affect the above-lying optical surfaces (in particular with the use of so called surface micro-machining with a deposited structural layer), chemically treated water repellent surfaces can change characteristics with time, and a possible generation of surface roughness can come to damage other critical surfaces in the system than the surfaces which shall get a reduced contact area.

An example of an MEMS which is very successful, but also very complicated, is the DMD mirror matrices that are produced by Texas Instruments and which are described in, for example, U.S. Pat. No. 7,411,717 and more specifically with regard to the problems related to stiction in US2009/0170324. In the manufacture of this product many of the methods described above are used.

The problem with producing spacer blocks and at the same time avoiding roughness of the surfaces which later shall be joined together or be laminated is considered in, among others, US2009/0170312. There are several disadvantages of the method presented in US2009/0170312. The under-etching process is difficult to control, therefore there is a practical limit on the minimum reproducible lateral size of the anti-bonding stops. Also, the surfaces of the anti-bonding stops will be relatively smooth, which is a disadvantage if bonding shall be prevented. Further, the oxidation process will alter the top surface as well as the cavity, restricting the use of diffractive surfaces instead of plane mirrors.

Many of the prior art examples with spacer blocks use a so called sacrifice layer. During the manufacture of the micro system, the sacrifice layer lies between what shall become movable micro structures and fixes these. The sacrifice layer is often made from silicon dioxide, but can also be made from a different material, for example, a polymer. The sacrifice layer is removed towards the end of the processing with the help of etching. A challenge with the removal of the oxide layer can be to get the etching process to be sufficiently selective, so that it removes the sacrifice layer only and no other material. A further two challenges arise if an etching liquid must be used: To get the liquid to penetrate into the micro cavities, and to get the cavities dry after the etching.

EP 1561724 presents an accelerometer where dimples may be included on the bottom of a recess in order to prevent stiction. However, there is no hint to how these dimples may be realized. Creating fine structures on the bottom surface of large KOH or TMAH etched recesses is very difficult, especially when standard MEMS production equipment is used.

U.S. Pat. No. 6,528,887 presents a medium complex method to manufacture the spacer blocks on the underside of a structural layer. Such layers normally consist of silicon, and in MEMS terminology they are referred to as device layers. In the introduction of said patent (2-8) it is claimed that it is generally not possible to process the underside of a MEMS device layer to form spacer blocks before this is laminated with a substrate. Furthermore, it is referred to how spacer blocks can be formed by processing from the top side of the device layer, together with the use of a sacrifice layer between the substrate and the device layer (an often used method).

The object of the present invention is to provide a micromechanical unit and a method for producing the micromechanical unit, the unit being cheap in production and easy to control having reduced stiction between the moveable beams. This is provided with a unit and method as stated above being characterized as stated in the independent claims.

The present invention thus provides a practical method to construct a such row, where in the preferred embodiment the fixed and movable optically reflecting surfaces are made up of the top sides of fixed and movable beams that are etched out from one and the same material layer. The fixed beams are permanently connected to a substrate via a thin dielectric layer, while the movable beams span across etched recesses in the substrate. They can thereby be pulled down towards the substrate by an electrostatic force until the bottom of the beams meet spacer blocks at the bottom of the recesses. The spacer blocks are shaped to give a small contact area and thus weak adhesive forces, something that ensures that the movable beams can return to the starting point when the electrostatic force ceases to function, and is made and machined from the same dielectric layer fixing the fixed beams to the substrate.

In the description that follows it is shown that it is actually possible, in a practically feasible and relatively simple way, to form spacer blocks by processing the top side of the substrate and/or the underside of the device layer before the joining together/lamination, in such a way that one achieves both good lamination characteristics and good, stiction-free spacer blocks. The solution which is presented is particularly well suited to form rows of alternatingly fixed and movable structures.

The invention will be described below with reference to the accompanying drawings, illustrating the invention by way of examples, wherein

FIGS. 0a,b illustrates the prior art as disclosed in abovementioned WO2004/059365

FIG. 0c illustrates the principle of the prior art.

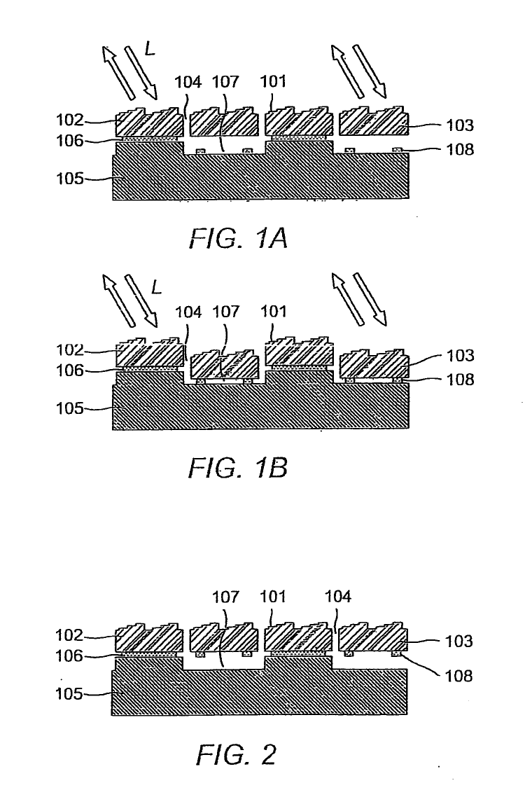

FIG. 1a,b illustrates the preferred embodiment of the present invention.

FIG. 2 illustrates an alternative embodiment of the present invention.

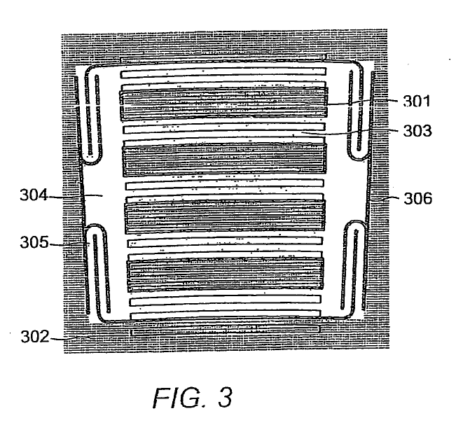

FIG. 3 illustrates an an embodiment of the present invention as seen from above.

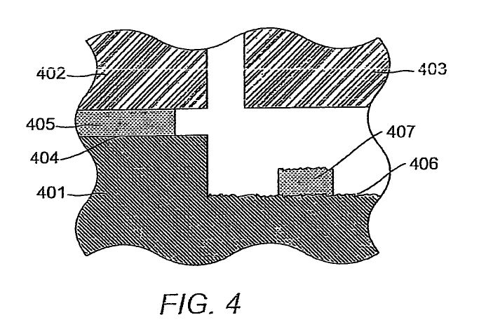

FIG. 4 illustrates a detail of the embodiment illustrated in FIGS. 1a,b.

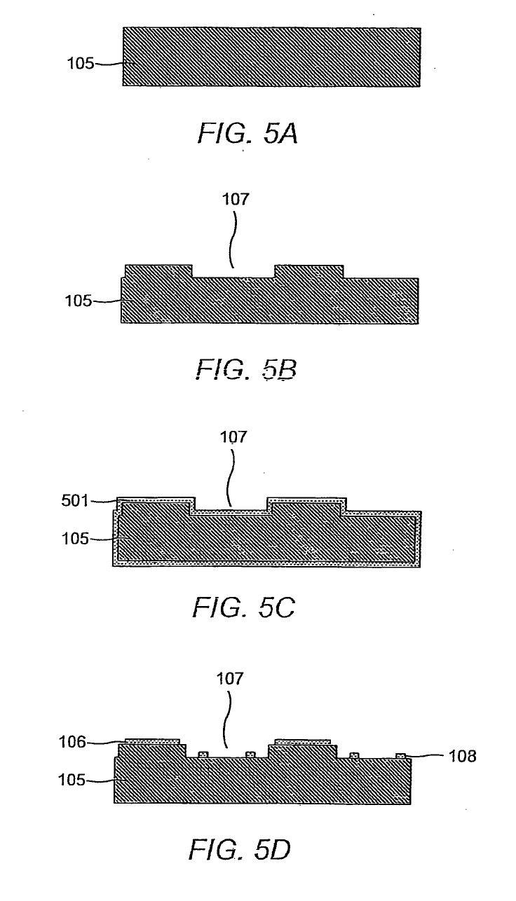

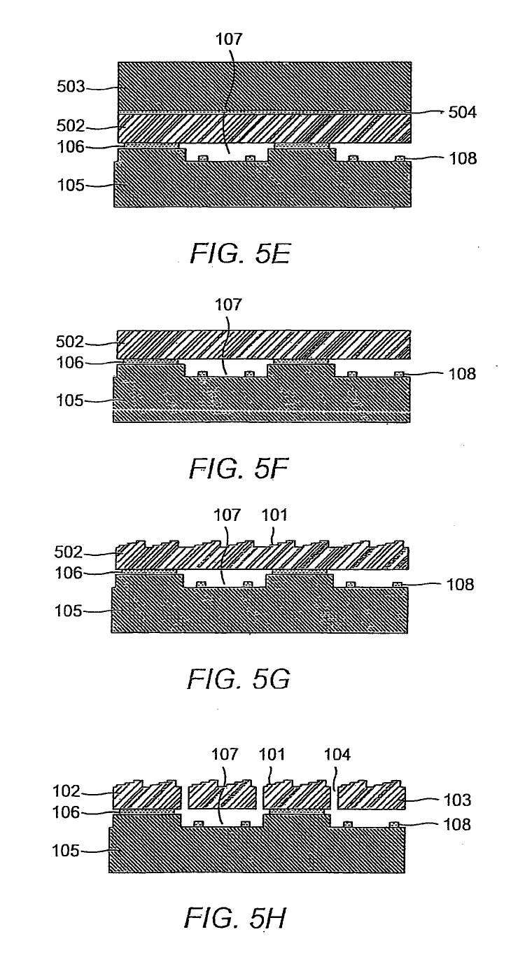

FIG. 5a-h illustrates the production method according to the preferred embodiment of the invention.

The invention thus comprises a new method for the manufacture of a micro electromechanical system that functions as an alternating optical filter as described in the above mentioned article in OMEMS2007. Central to the new method is the use of a substrate and a thinner layer of material, generally with a thickness of the order of 5-50 μm, both preferably made from silicone, which are prepared in such a way that when they are joined together, some areas will have maximum adhesion, and other areas will have minimal adhesion. In the areas with minimal adhesion, spacer blocks are used to reduce the adhesive forces and avoid stiction.

Referring to FIGS. 1a and 1b the fixed and movable optical micro reflectors (101) mentioned in the introduction are made up of the top side of the fixed (102) and movable beams (103) that are cut/machined/etched out from a material layer. The beams are illustrated as straight, but can also have other shapes as shown in the above mentioned WO publication. The fixed beams are permanently connected to a substrate (105) via a thin dielectric layer (106), while the movable beams are spanning out over etched recesses (107) in the substrate. Thereby, they can be pulled down towards the substrate by an electrostatic force until they are stopped by the spacer blocks (108), which can be at the bottom of the recesses or on the underside of the beams (as shown in FIG. 2). An essential feature of the present invention is that the spacer blocks are made from the same dielectric layer that fastens the fixed beams to the substrate. The spacer blocks are shaped to give a small contact area and thus weak adhesion forces, something which ensures that the movable beams can be returned to their initial position when the electrostatic force ceases to function. Thus the incoming light L may be manipulated by the diffractive patterns depending on the relative positions of the beams.

Using contact lithography and anisotropic etching the diameter of the spacer blocks can be made less than a micrometer, and using a so-called stepper or reduction lithography it is in principle possible to obtain dimensions less than 100 nm.

The force that makes the beams return to their initial position is in one embodiment of the invention (shown in FIG. 3) generated in that the movable beams (303) are connected together to a common (movable) frame (304), and this frame is connected to a fixed, outer area (302) via small, elastic bridges (springs) (305). These springs will be bent when the frame is moved and thus create an upwardly directed force that attempts to bring the frame back to its starting position. To move the frame with the optical surfaces the desired distance away from the starting position an electrostatic field is used that is created by applying a voltage between the substrate and the device layer and thereby, at least, the movable beams. If the voltage is sufficiently high, the frame will be pulled all the way in to the spacer blocks that lie in the recesses in the substrate, as shown in FIG. 1B.

The invention provides a simple and robust solution for the mechanical challenge that lies in the displacement of the optical surfaces. The combination of the process steps that are described in detail below ensures that:
1) The desired displacement distance can be determined freely via the depth of the etched recesses,
2) The contact area is reduced on a nano scale in that the etching creates a rough surface,
3) The contact area is reduced on a micro scale in that the extension of the spacer blocks is made as small as possible,
4) Good fixed adhesion to the fixed beams is ensured, by, for example, protection of the chosen polished surfaces during the etching,
5) The form, thickness and location of the spacer blocks can be freely determined without the optical surfaces being affected,
6) The optical surfaces lie on the top side of thick beams which are approximately free for internal mechanical tensions,
7) The micro system can be completed without the complicated removal of a “sacrifice” layer, as is often the case in known methods, for example, as shown in FIG. 0C.

FIG. 4 shows in greater detail the difference between the surface of the substrate (401) under a fixed (402) and a movable (403) beam. The substrate has initially a smooth (polished) surface (404) as shown below the dielectric layer (405). The etching of the recesses will result in a rougher surface (406) and this roughness is largely kept after the deposition or growth of the dielectric layer that is to become the spacer blocks (407). It can be an advantage that the spacer blocks have a rough surface to further reduce the contact area and the adhesive forces. Consequently, the total contact area between the spacer blocks ought to be as small as possible, preferably less than 1%, but they must also be sufficiently large so that they do not yield too much when the beams are placed against them and have a distribution along the beams that prevents the bending of these.

The dielectric layer that lies on the substrate outside the recesses will have a much smoother surface than the spacer blocks as it is formed on top of a polished surface.

Here, it is desirable to have a large adhesive force/energy to achieve a good joining together with the static parts of the structural layer.

Even if the same dielectric layer can form both the joined together layer and the spacer blocks, the previous etching process can give the surface of the layer different characteristics in the two areas.

In a preferred embodiment (FIGS. 5A-H), the invention comprises a method where one starts with a substrate (105) which has a polished top side (FIG. 5A). Recesses (107) are etched into the substrate with a depth that corresponds to the displacement distance of the beams (FIG. 5B), for example, 830 nm, if light with a wavelength of around 3.3 μm shall be measured, for example, in the measuring of methane or other hydrocarbons, but adapted to about ¼ of the wavelength of the light the element shall be used on. The etching process can be a reactive ion etching with a mixture of SF₆ and C₄F₈ and with a calibration of the etching time one can achieve a depth accuracy of the order of ±5%. Thereafter, a dielectric layer (501) is deposited, or grown, for example, thermally grown silicone dioxide, which thereafter is etched away in some areas to form the spacer blocks (108) (FIGS. 5C-D). FIG. 5E shows how the device layer (502) is fused together with the substrate (105) with the help of a wafer lamination method (for example, fusion bonding) and a handling wafer (503) that is ground or etched away (FIG. 5F). When the device layer is fused with the substrate, a very good adhesion will be achieved in the areas that are without the recesses, for one thing because the surface is very smooth after the polishing and also after the dielectric layer has been deposited or grown on the substrate.

The optical surfaces (101) are engraved with the help of, for example, a reactive ion etching, with a diffractive relief pattern (FIG. 5G) before the device layer is cut through and narrow through-going trenches (104) that separate the fixed and movable beams (FIG. 5H) appear. The cutting through is carried out in such a way that there are small connections (bridges) in some places from the movable segments to the fixed segments, as shown in FIG. 3. The preferred way to carry out this cutting through is a reactive ion etching, known as the “Bosch process”.

In an alternative solution the process steps shown in FIGS. 5C and 5D are carried out on the underside of the device layer so that the substrate is without a dielectric layer before the merging and the spacer blocks sit under the movable beams. In other alternative solutions, the etched recesses, or both the recesses and the spacer blocks, can be on the underside of the device layer. A disadvantage with the mentioned alternative solutions is that the device layer must be lined up accurately against the substrate.

The surface of the device layer is finally covered with a thin metal layer (metal film) so that the light shall be reflected. This layer must be very thin and/or have a low inner mechanical tension for the optical surfaces to be sufficiently plane. A thin layer with a high inner mechanical tension will make the device layer curve. The thermal coefficient of expansion of the metal layer should not be too different from the coefficient for the device layer. A possible solution is to use two films (for example Al and SiO₂) to obtain a stress balance and not least thermal compensation (balanced expansion).

Both the substrate and the device layer are given a desired electrical conductivity in advance with the help of doping. When an electric voltage is applied between the substrate and the device layer, an electrostatic force will arise, which pulls the movable segments of the device layer down towards the substrate. In the embodiment shown in FIG. 3 the electric potential of the isolated fixed beams (301) will be undefined (floating), as long as no connection is made, for example, with through-etching down to the substrate and deposition of a conducting material. As long as the gap between the beams is sufficiently large, and the beams are considerably wider than they are thick, the undefined electric potential will not influence the movement of the movable beams. When the underside of the movable segments meets the top side of the dielectric spacer blocks, the displacement will stop. Simultaneously with the displacement, an elastic deformation of the bridge connection from the movable to the fixed areas of the device layer will take place so that when the electrical potential difference is removed, the force that is set up from the elastic deformation will make the movable segments return to their initial positions. However, there is one requirement for this to take place: The adhesive forces between the spacer blocks and the silicone segments must be weaker than the forces set up from the beams/bridges/springs. The invention ensures that this is the case, through the described etching processes of the substrate and dielectricum, to minimise the contact area on both the nano scale (roughness) and micro scale (boundary of the spacer blocks). The same material (silicone oxide) will have a completely unique adhesion to the silicone, dependent on the etching processes that have been carried out, and thus function both as a joining together layer and spacer blocks.

In addition to minimising the contact area, there is also another reason that the spacer blocks should cover a limited area: Parasitic charging of dielectric materials can lead to unwanted electrostatic adhesive forces. This is described in, among others, an article by Webber et al, “Parasitic charging of dielectric surfaces in capacitive microelectromechanical systems (MEMS)” published in Sensors and Activators A 71 (1998), page 74-80.

The placing of the spacer blocks can be made nearly arbitrarily and in one preferred solution they are placed such that the movable frames are lifted away from a small number of spacer blocks at a time, as the principle is for Velcro. Even if the adhesive energy is large, the adhesive force can be made small in that it only functions on a small area at any time.

The invention thus also provides a solution where the thickness and placing of the spacer blocks do not influence the device layer and the characteristics of the optical surfaces, something that means that the placing can be made nearly solely with regard to the stiction characteristics and the deformation of the beams when they have been moved. The thickness of the dielectric layer which forms both the spacer blocks and the joined together layer (between the substrate and the device layer) is a free parameter which can be used to adjust the electrical field force in the air gap.

In the version shown in FIG. 3, the surface of the device layer comprises five different types of area: Static, passive area; movable passive area; static active area; movable active area; and also spring beams (transition between static and movable area). The difference between passive and active areas is that the latter has a periodic or nearly periodic relief structure that bends the light in the desired direction.

A preferred embodiment of the invention is shown in FIG. 1A (initial state, state A) and FIG. 1B (moved state, state B). The optical surfaces (101) are at the top of fixed (102) and movable (103) beams, where the beams are manufactured from the same material layer/device layer (doped silicone) by cutting through (104) (with reactive ion etching). The fixed beams are permanently connected to a substrate (105) (of silicone) via a dielectric layer (106) (silicone dioxide). There are recesses (107) in the substrate below the movable beams and at the bottom of the recesses there are spread out areas of a dielectric layer in the form of spacer blocks (108).

FIG. 1B shows how the row of beams appears when it has been moved. The movable beams are pulled downwards towards the substrate by an electrostatic force until they stop on the spacer blocks (108). In a preferred embodiment the joined together layer (106) and the spacer blocks (108) are formed from the same layer and have the same thickness. The thickness of the spacer blocks (108) will thereby not influence the displacement distance, which is defined by the recesses in the substrate only. The correct displacement distance can be reached in that the recesses are etched with exact timing and a calibrated etching process.

FIG. 2 shows an alternative embodiment where the spacer blocks (201) are attached to the underside of the movable beams (202).

FIG. 3 shows a possible embodiment of the row of beams viewed from above. An arbitrary number N (here: N=4) of fixed beams (301) is permanently connected to the substrate via a dielectric layer. In addition, the outer area (302) is also connected to the substrate. A number N+1 (here: N+1=5) of movable beams (303) is connected together to a common (movable) frame (304) and this frame is connected to the fixed, outer area (302) through narrow, elastic bridges (springs) (305). These springs will be curved when the frame is moved and thus generate a correcting force that attempts to bring the frame back to its original position. To move the frame with the optical surfaces the desired distance away from the initial position, an electrostatic field is use, which is set up by applying a voltage between the substrate and the device layer.

FIG. 4 shows in more detail the difference between the surface of the substrate (401) below a fixed (402) and movable (403) beam. The substrate has initially a smooth (polished) surface (404) as shown below the dielectric layer (405). The etching of the recesses will result in a rougher surface (406) and this roughness is, to a large extent, kept after the placing of the dielectric layer which shall become the spacer blocks (407).

FIG. 5 shows a preferred embodiment where one starts with a substrate (105) that has a polished top side (FIG. 5A). Recesses (107) are etched into the substrate with a depth that corresponds to the displacement distance of the beams (FIG. 5B). A dielectric layer (501) is put on or grown which thereafter is etched away in some areas to form the spacer blocks (108) (FIGS. 5C-D). FIG. 5E shows how the device layer (502) is joined together with the substrate (105) with the help of a handling wafer (503) that can be ground or etched away (FIG. 5F) so that one obtains, for example, a thickness of 15 μm. The desired thickness can be obtained as shown in the figure by using a so called SOI wafer, which is a laminate with a buried oxide layer, where the thickness of the device layer (502) is specified with good accuracy. The grinding and the etching of the SOI wafer can be stopped at the oxide layer. A second alternative is to use a homogeneous wafer instead of the laminate 502/503/504. The grinding/etching must then be controlled by measurements of the remaining layer and the surface of the device layer must be polished at the end. Afterwards, the optical surfaces (101) are engraved with a diffractive relief pattern (FIG. 5G) before the device layer is cut through and narrow through-going ditches (104) are formed, that separate the fixed and movable beams (FIG. 5H).

To summarize the invention thus relates to a micromechanical system and a method to construct a microelectromechanical system comprising a row of alternatingly fixed and movable (diffractive) optical reflectors, where the reflectors are made up from the top sides of the fixed and movable beams that are formed from one and the same material layer, and where said beams are directly or indirectly connected to a substrate, and where the connection between the material layer and substrate is formed after the underside of the material layer or the top side of the substrate is treated by an etching of recesses in chosen areas, a placing of a thin dielectric layer, and an etching of said layer in chosen areas, for the purpose of achieving a strong and fixed adhesion between the substrate and the fixed beams and a weak adhesion between the substrate and the underside of the movable beams using the same dielectric material.

It is preferred that the substrate and the material layer are comprised of silicone, but other materials can also be used dependent on the production methods and applications.

The optical reflectors have preferably a diffractive relief pattern/synthetic hologram, for example, linear or curved, but pure reflecting surfaces can also be imagined.

The connection between the substrate and the material layer is preferably formed with the help of fusion bonding and the dielectric layer can be deposited or grown on said substrate and/or on the material layer. Correspondingly, the recesses can be etched in the substrate and/or in the material layer, for example, with reactive ions.

In a realised embodiment, the number of beams per frame can be between 2 and 20, and the division between movable and fixed parts of the material layer are created by a deep reactive ion etching. The lateral extension of the spacer blocks is 0.5-5 μm and the thickness of the spacer blocks is 100 nm-2 μm.

Each frame can have four springs which can result in a symmetrical suspension such that it is lifted from, or lowered towards, the spacer blocks evenly, or the suspension can be asymmetrical so that one side of the frame comes up more easily than the others.

As mentioned above, the movement between the movable, reflecting beams/elements and the underlying substrate is produced by applying a voltage between them. The non-movable beams can be held in a floating voltage or be given a concrete voltage dependent on how this will influence the movement of the movable beams.

The figures illustrate the invention with the help of examples, and the ratios and dimensions in drawings are only chosen for purposes of illustration and can deviate from realised embodiments.

1. A micromechanical unit comprising:
a first device layer and a second substrate layer at least partially fastened to each other;
wherein the first device layer comprises a number of moveable reflecting elements distributed between a number of fixed reflecting elements;
wherein the fixed reflecting elements are fastened to the second substrate layer through a dielectric layer;
wherein a cavity is defined in the second substrate layer and each movable reflecting element, each said movable reflecting element being set up to provide a controllable movement into the cavity;
wherein a number of dielectric spacer blocks are placed in the cavities between each movable reflecting element and the second substrate layer in which the cavity is made;
wherein the spacer blocks are made in the same dielectric material as said dielectric layer fastening the substrate to the fixed reflecting elements, the spacer blocks being positioned at the substrate within said cavities; and
wherein the cavities are provided into said substrate using an etching process.

2. The unit according to claim 1, wherein the movable elements and the substrate are connected to a voltage source to apply a voltage between the movable elements and the substrate to create an electrostatic force between them and thereby move the element in relation to the substrate.

3. The unit according to claim 1, wherein a dielectric layer separates all the beams from the substrate, where the dielectric layer has an even thickness and where it constitutes the spacer blocks between the movable beams and the substrate.

4. The unit according to claim 1, wherein the spacer blocks have a contact surface against the movable beams which encompasses a considerably smaller part of the total area of the beams, preferably less than 1%.

5. The unit according to claim 1, wherein the unit is an optical filter and where the depth of the cavities are of the order of ¼ of the wavelength of the light in the relevant area.

6. A method to produce the unit according to claim 1, with a number of movable beams of a predetermined form comprising the following steps:
a) using an etching process formation of a number of recesses in a substrate wafer of a selected material with a chosen depth in a surface on the substrate wafer, where the recesses present a pattern on the surface of the substrate corresponding to the placing and form of the movable beams;
b) providing a dielectric layer on the surface of the substrate wafer with the recesses;
c) removing said dielectric layer in said recesses providing a pattern defining spacer blocks in predetermined positions in said recesses;
d) fastening of an upper device layer on said dielectric layer; and
e) dividing the upper layer to form movable beams in said pattern over said recesses.

7. The method according to claim 6, wherein step c) comprises etching of the dielectric layer in the recesses to form separate spacer blocks with a height that corresponds to the thickness of the dielectric layer and set up to have a contact surface against the movable beams that constitutes a considerably smaller part than the area of the beams.

8. The method according to claim 6, wherein step d) encompasses a so called fusion bonding process.

9. The method according to claim 6, wherein the upper device layer is supplied with a reflecting surface.

10. The method according to claim 6, wherein the upper device layer is supplied with a diffractive relief pattern.
